(19) United States
(12) Patent Application Publication
(10) Pub. No.: US 2022/0291706 A1
(43) Pub. Date: Sep. 15, 2022

(54) LINEAR VOLTAGE REGULATOR WITH FAST LOAD REGULATION AND METHOD THEREOF

(71) Applicant: Realtek Semiconductor Corp., Hsinchu (TW)

(72) Inventor: Chia-Liang (Leon) Lin, Fremont, CA (US)

(21) Appl. No.: 17/249,691

(22) Filed: Mar. 10, 2021

(51) Int. Cl. G05F 1/59; G05F 1/575; H03F 3/45

(52) U.S. Cl. CPC G05F 1/59; G05F 1/575; H03F 3/45179

(57) ABSTRACT

A linear voltage regulator includes an error amplifier configured to receive an output voltage at an output node and a reference voltage at a reference node and output a first control voltage; a first PMOS transistor configured to receive an input voltage from a power supply node and output a first output current to the output node in accordance with the first control voltage; an AC coupling capacitor configured to couple the output voltage to an AC coupled voltage; a high-speed amplifier configured to receive the AC coupled voltage and output a second control voltage; a second PMOS transistor configured to receive the input voltage and output a second output current to the output node in accordance with the second control voltage; and a load configured to draw a load current from the output node.

### BACKGROUND OF THE DISCLOSURE

### Field of the Disclosure

The present disclosure generally relates to linear voltage regulator, and more particularly to a voltage regulator and associated method having fast load regulation.

### Description of Related Art

As is known, a linear voltage regulator receives an input voltage from a power supply and output an output voltage to a load in accordance with a reference voltage, such that the output voltage remains approximately equal to the reference voltage regardless of the load. A schematic diagram of a prior art linear voltage regulator 100 is shown in FIG. 1. Linear voltage regulator 100 comprises: an error amplifier 111 configured to receive an output voltage Vₒᵤₜ (at an output node 101) and a reference voltage V_{ref} (at a reference node 102) and output a control voltage V_{ctl}; a PMOS (p-channel metal oxide semiconductor) transistor 112 configured to receive an input voltage Vₛᵤₚ from a power supply node 103 and output an output current Iₒᵤₜ to the output node 101 in accordance with a control by the control voltage V_{ctl}; and a load 120 configured to draw a load current I_{load} from the output node 101.

In an embodiment, linear voltage regulator 100 further comprises a shunt capacitor 113 configured to shunt the output node 101 to ground. Linear voltage regulators 100, like that of FIG. 1 are well known in the prior art and thus not described in detail here. A purpose of linear voltage regulator 100 is to utilize a negative feedback control loop formed by the error amplifier 111 and the PMOS transistor 112 to control the output current Iₒᵤₜ in a closed-loop manner to match the load current I_{load} so that the output voltage Vₒᵤₜ can be stable and remain approximately the same as the reference voltage V_{ref} regardless of the load current I_{load}. Here, the error amplifier 111 functions as a controller and the PMOS transistor 112 functions as an output device controlled by the controller. In practice, the output voltage Vₒᵤₜ will deviate from the reference voltage V_{ref} depending on the load current I_{load}. A large sudden increase (decrease) of the load current I_{load} usually leads to a large sudden fall (rise) of the output voltage Vₒᵤₜ. This is because the negative feedback control loop is subject to instability and cannot be designed to have a sufficiently wide bandwidth to increase (decrease) the output current Iₒᵤₜ in time to match the increase (decrease) of the load current I_{load}, causing an instant change of a charge stored on the shunt capacitor 113 and consequently an instant change of the output voltage Vₒᵤₜ.

What is desired is a linear voltage regulator with a fast load regulation, such that a large sudden change of a load current does not cause a large sudden change of the output voltage.

### SUMMARY OF THE DISCLOSURE

In an embodiment, a linear voltage regulator comprises: an error amplifier configured to receive an output voltage at an output node and a reference voltage at a reference node and output a first control voltage; a first PMOS (p-channel metal oxide semiconductor) transistor configured to receive an input voltage from a power supply node and output a first output current to the output node in accordance with the first control voltage; an AC (alternate current) coupling capacitor configured to couple the output voltage to an AC coupled voltage; a non-inverting amplifier configured to receive the AC coupled voltage and output a second control voltage; a second PMOS transistor configured to receive the input voltage and output a second output current to the output node in accordance with the second control voltage; and a load configured to draw a load current from the output node.

In an embodiment, a method of voltage regulation comprises: receiving an input voltage and a reference voltage; incorporating a load configured to draw a load current from an output node; establishing a first control voltage in accordance with a difference between the reference voltage and an output voltage at the output node using an error amplifier; converting the input voltage into a first output current supplied to the output node using a first PMOS (p-channel metal oxide semiconductor) transistor in accordance with the first control voltage; coupling the output voltage to an AC (alternate current) coupled voltage using an AC coupling capacitor; amplifying the AC coupled voltage into a second control voltage using a non-inverting amplifier; and converting the input voltage into a second output current supplied to the output node using a second PMOS transistor in accordance with the second control voltage.

### BRIEF DESCRIPTION OF THE DRAWINGS

FIG. 1 shows a schematic diagram of a prior art linear voltage regulator.

FIG. 2A shows a schematic diagram of a linear voltage regulator in accordance with an embodiment of the present disclosure.

FIG. 2B shows a schematic diagram of an error amplifier in accordance with an embodiment of the present disclosure.

FIG. 2C shows a schematic diagram of a non-inverting amplifier in accordance with an embodiment of the present disclosure.

FIG. 3 shows a simulation result of the linear voltage regulator of FIG. 2A.

FIG. 4 shows a flow diagram of a method of voltage regulation in accordance with an embodiment of the present disclosure.

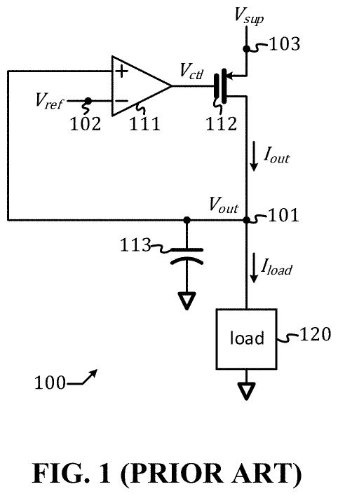

### DETAILED DESCRIPTION OF THIS DISCLOSURE

The present disclosure is directed to voltage regulator circuits and related methods. While the specification describes several example embodiments of the disclosure considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the disclosure.

Persons of ordinary skill in the art understand terms and basic concepts related to microelectronics that are used in this disclosure, such as “circuit node,” “power supply node,” “ground node,” “differential pair,” “voltage,” “current,” “MOS (metal oxide semiconductor)” “CMOS (complementary metal oxide semiconductor),” “PMOS (P-channel metal oxide semiconductor) transistor,” “NMOS (N-channel metal oxide semiconductor) transistor,” “amplifier,” “non-inverting amplifier,” “common-source amplifier,” “class-AB amplifier,” “operational amplifier,” “single-stage amplifier,” “voltage gain,” “negative feedback control loop,” “stability,” “frequency compensation,” “two-stage amplifier,” “non-inverting amplifier,” “AC (alternate current),” “AC (alternate current) couple,” “DC (direct current),” “DC (direct current) couple,” “current source,” and “load.” Terms and basic concepts like these, when used in a context of microelectronics, are apparent to those of ordinary skill in the art and thus will not be explained in detail here.

Those of ordinary skill in the art can read schematics of a circuit comprising components such as capacitors, resistors, NMOS transistors, PMOS transistors, and so on, and do not need a verbose description about how one component connects with another in the schematics. Those of ordinary skill in the art can also recognize a ground symbol and symbols of PMOS transistor and NMOS transistor, and identify the “source terminal,” the “gate terminal,” and the “drain terminal” thereof. Pertaining to a MOS transistor, for brevity, hereafter, “source terminal” is simply referred to as “source,” “gate terminal” is simply referred to “gate,” and “drain terminal” is simply referred to “drain.” Those of ordinary skill in the art also understand units such as V (Volt), A (Ampere), mV (mini-Volt), mA (milli-Ampere), dB (Decibel), μs (micro-second), ns (nano-second), mm (millimeter), nm (nanometer), Ohm, KOhm (kilo-Ohm), pF (pico-Farad), nF (nano-Farad), and μF (micro-Farad), and thus no explanation of these basic concepts are needed herein.

A MOS transistor, PMOS or NMOS, has a width and a channel length. Sometimes, “channel length” is simply stated as “length” for short when it is obvious from the context that the “length” refers to the “channel length” of the transistor without causing confusion. Width and length of a MOS transistor are referred by a notation “W/L.” For instance, when it is said that “W/L of a NMOS transistor are 1 mm/30 nm,” it means that “width and length of a NMOS transistor are 1 mm and 30 nm, respectively.”

This disclosure is presented in an engineering sense, instead of a rigorous mathematical sense. For instance, “A is equal to B” means “a difference between A and B is smaller than an engineering tolerance. “X is zero” means “an absolute value of X is smaller than an engineering tolerance.”

In this disclosure, a “circuit node” is frequently simply stated as a “node” for short, when what it means is clear from the context.

Throughout this disclosure, a ground node is a node of substantially zero voltage (0V). A power supply node is a node of a substantially fixed voltage and is denoted by “V_{DD},” which is a convention widely used in the literature. In this disclosure, depending on a context that is apparent to those of ordinary skill in the art, sometimes “V_{DD}” refers to the voltage level at the power supply node “V_{DD}.” For instance, it is apparent that when we say “V_{DD} is 1.5V” it means that the voltage level at the power supply node V_{DD} is 1.5V.

A DC (direct current) node is a node of a substantially stationary voltage level. Both a power supply node and a ground node are a DC node.

A circuit is a collection of devices including one or more of a transistor, a capacitor, a resistor, and/or other electronic devices inter-connected in a certain manner to embody a certain function. A network is a circuit or a collection of circuits.

An error amplifier is a circuit configured to receive a first input voltage and a second input voltage and output an output voltage such that a value of the output voltage is equal to a fixed value plus a variable value that is approximately proportional to a difference between the first input voltage and the second input voltage, wherein the difference represents an error.

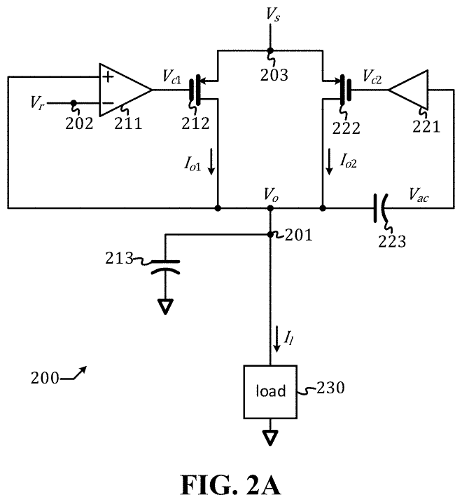

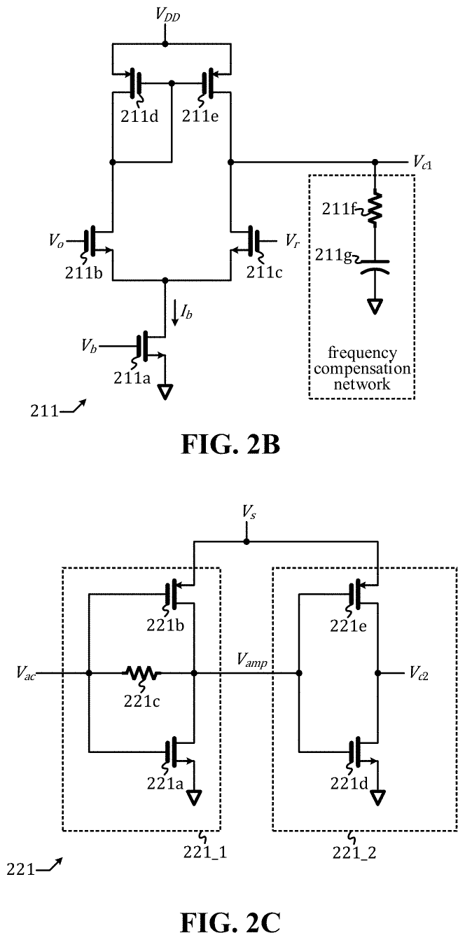

A schematic diagram of a linear voltage regulator 200 in accordance with an embodiment of the present disclosure is shown in FIG. 2A. Linear voltage regulator 200 comprises: an error amplifier 211 configured to receive an output voltage Vₒ (at an output node 201) and a reference voltage Vᵣ (at a reference node 202) and output a first control voltage V_{c1}; a first PMOS transistor 212 configured to receive an input voltage Vₛ (at a power supply node 203) and output a first output current Iₒ₁ to the output node 201 in accordance with a control of the first control voltage V_{c1}; an AC (alternate current) coupling capacitor 223 configured to couple the output voltage Vₒ to an AC coupled voltage V_{ac}; a non-inverting amplifier 221 configured to receive the AC coupled voltage V_{ac} and output a second control voltage V_{c2}; a second PMOS transistor 222 configured to receive the input voltage Vₛ (at the power supply node 203) and output a second output current Iₒ₂ to the output node 201 in accordance with a control of the second control voltage V_{c2}; and a load 230 configured to draw a load current Iₗ from the output node 201. In an embodiment, the linear voltage regulator 200 further comprises a shunt capacitor 213 configured to shunt the output node 201 to ground.

Error amplifier 211 and the first PMOS transistor 212 form a first negative feedback control loop, while AC coupling capacitor 223, non-inverting amplifier 221, and the second PMOS transistor 222 form a second negative feedback control loop. The first negative feedback control loop is a DC (direct current) coupling, low-speed loop configured to gradually adjust the first output current Iₒ₁ to track a change of an average value of the load current Iₗ; the second negative feedback control loop is an AC coupling high-speed loop configured to promptly adjust the second output current Iₒ₂ to track a sudden change of an instantaneous value of the load current Iₗ. The first negative feedback loop ensures that in a steady state the output voltage Vₒ is approximately equal to the reference voltage Vᵣ, while the second negative feedback loop ensures that the output voltage Vₒ does not have a big fluctuation in the presence of a large sudden change of the load current Iₗ and can quickly recover from the disturbance caused by the sudden change. The first negative feedback control loop does not need to have a wide bandwidth, therefore the constraint set by stability is much relaxed. The second negative feedback loop needs to have a wide bandwidth and is thus subject to instability. However, the AC coupling effectively introduces a zero in the transfer function of the feedback loop that helps to improve stability. Here, “transfer function,” “feedback loop,” and “zero” are stated in a context of control theory and the related concepts are well understood by those of ordinary skills in the art and thus not described in detail here.

A schematic diagram of an exemplary embodiment of error amplifier 211 is shown in FIG. 2B. Error amplifier 211 is embodied by a single-stage operational amplifier that comprises: a NMOS transistor 211a embodying a current source configured to establish a bias current I_{b} in accordance with a bias voltage V_{b}; two NMOS transistors 211b and 211c embodying a differential pair configured to amplify a difference between the output voltage Vₒ and the reference voltage Vᵣ into the first control voltage V_{c1} based on using the bias current I_{b}; and two PMOS transistors 211d and 211e embodying an active load for said differential pair to fulfill a differential-to-single-ended conversion. Here, “V_{DD}” denotes a power supply node. Error amplifier 211 is a circuit well known in the prior art and thus not described in detail here. In a further embodiment, error amplifier 211 further includes a frequency compensation network comprising a series connection of a resistor 211f and a capacitor 211g that is used to improve a stability of the first negative feedback control loop. The concept of frequency compensation is well known in the prior art and thus not described in detail herein.

A schematic diagram of an exemplary embodiment of non-inverting amplifier 221 is shown in FIG. 2C. Non-inverting amplifier 221 is a two-stage amplifier comprising an input stage 221_1 configured to receive the AC coupled voltage V_{ac} and output an amplified voltage Vₐₘₚ, and an output stage 221_2 configured to receive the amplified voltage Vₐₘₚ and output the second control voltage V_{c2}. A purpose of the input stage 221_1 is to provide a high gain, so that a small change in the AC coupled voltage V_{ac} can be amplified into a large change in the amplified voltage Vₐₘₚ. A purpose of the output stage 221_2 is to provide a high driving capability, so that a large change in the amplified voltage Vₐₘₚ can lead to a large change in the control voltage V_{c2} despite a heavy load presented by the second PMOS transistor 222. By way of example but not limitation, the input stage 221_1 is a common-source amplifier embodied by a self-biased inverter that comprises NMOS transistor 221a, PMOS transistor 221b, and a self-biasing feedback resistor 221c; the output stage 221_2 is class-AB amplifier embodied by an inverter that comprises NMOS transistor 221d and PMOS transistor 221e. Concepts of “common-source amplifier,” “inverter,” “self-biasing,” and “class-AB amplifier” are well understood by those of ordinary skill in the art and thus not described in detail here. A class-AB amplifier can efficiently provide a high driving capability and is thus used to embody the output stage 221_2. In an embodiment, a voltage gain of the input stage 221_1 is larger than a voltage gain of the output stage 221_2. By way of example but not limitation, a voltage gain of the input stage 221_1 is approximately 16 dB, and a voltage gain of the output stage 221_2 is approximately 12 dB.

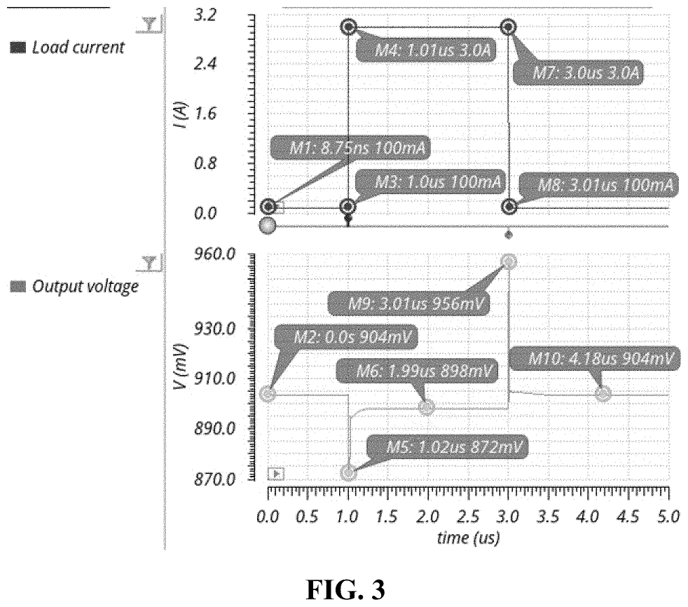

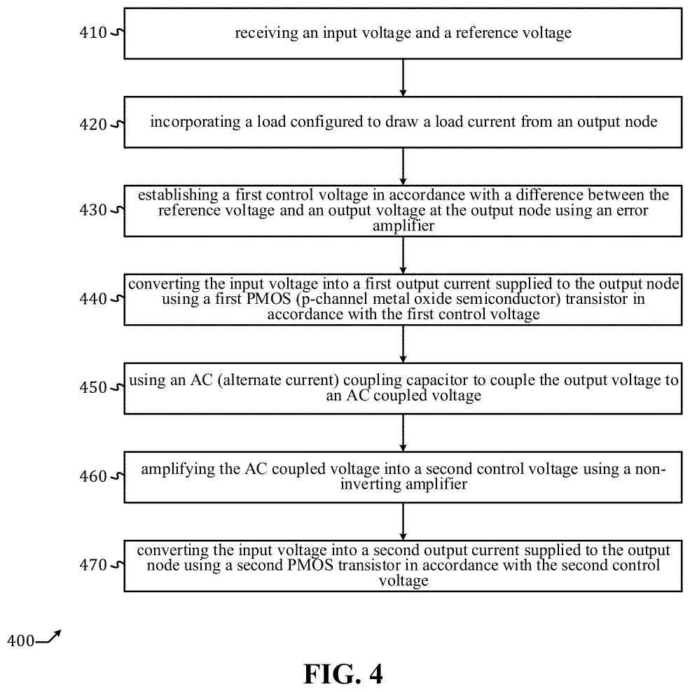

In an embodiment, linear voltage regulator 200 is integrated and fabricated on a silicon substrate using a CMOS process technology. By way of example but not limitation; a 22 nm CMOS process is used, wherein a minimum channel length is 30 nm; Vₛ is 1.1V; V_{DD} is 1.5V; Vᵣ is 0.9V; W/L (which stands for width/length) of NMOS transistor 211a are 2.5 mm/500 nm; V_{b} is 650 mV; I_{b} is 10 mA; W/L of NMOS transistors 211b and 211c are 1.25 mm/500 nm; W/L of PMOS transistors 211d and 211e are 1.25 m/500 nm; resistor 211f is 20 Ohm; capacitor 211g is 100 pF; W/L of PMOS transistor 212 are 16 mm/30 nm; AC coupling capacitor 223 is 5 pF; W/L of NMOS transistor 221a are 0.6 mm/30 nm; W/L of PMOS transistor 221b are 0.6 mm/30 nm; resistor 221c is 25 KOhm; W/L of NMOS transistor 221d are 1.2 mm/30 nm; W/L of PMOS transistor 221e are 2.4 mm/30 nm; W/L of PMOS transistor 222 are 16 mm/30 nm; and shunt capacitor 213 is embodied by a parallel connection of an on-chip capacitor of 11 nF and an off-chip capacitor of 11μF. A simulation result is shown in FIG. 3. Here, a waveform of the load current (Iₗ) and the output voltage (Vₒ) is shown. Initially, the load current is 100 mA (M1) and the output voltage is 904 mV (M2). The load current rapidly rises from 100 mA at time 1.0 μs (M3) to 3.0 A at time 1.01 μs (M4). Incidentally, the output voltage drops to 872 mV at time 1.02 μs (M5) but quickly rebounds and settles to 898 mV at 1.99 μs (M6). The load current rapidly falls from 3.0 A at time 3.0 μs (M7) to 100 mA at time 3.01 μs (M8). Incidentally, the output voltage rises to 956 mV at time 3.01 μs (M9) but quickly recedes and settles to 904 mV at 4.18 μs (M10). This demonstrates that the linear voltage regulator 200 has a very fast load regulation capability.

As demonstrated by a flow diagram 400 shown in FIG. 3, a method of voltage regulation in accordance with an embodiment of the present disclosure comprises: (step 410) receiving an input voltage and a reference voltage; (step 420) incorporating a load circuit configured to draw a load current from an output node; (step 430) establishing a first control voltage in accordance with a difference between the reference voltage and an output voltage at the output node using an error amplifier; (step 440) converting the input voltage into a first output current supplied to the output node using a first PMOS (p-channel metal oxide semiconductor) transistor in accordance with the first control voltage; (step 450) using an AC (alternate current) coupling capacitor to couple the output voltage to an AC coupled voltage; (step 460) amplifying the AC coupled voltage into a second control voltage using a non-inverting amplifier; and (step 470) converting the input voltage into a second output current supplied to the output node using a second PMOS transistor in accordance with the second control voltage.

Those skilled in the art will readily observe that numerous modifications and alterations of the device and method may be made while retaining the teachings of the disclosure. Accordingly, the above disclosure should not be construed as limited only by the metes and bounds of the appended claims.

What is claimed is:

1. A linear voltage regulator comprising:
an error amplifier configured to receive an output voltage at an output node and a reference voltage at a reference node and output a first control voltage;
a first PMOS (p-channel metal oxide semiconductor) transistor configured to receive an input voltage from a power supply node and output a first output current to the output node in accordance with the first control voltage;
an AC (alternate current) coupling capacitor configured to couple the output voltage to an AC coupled voltage;
a non-inverting amplifier configured to receive the AC coupled voltage and output a second control voltage;
a second PMOS transistor configured to receive the input voltage and output a second output current to the output node in accordance with the second control voltage; and
a load configured to draw a load current from the output node.

2. The linear voltage regulator of claim 1, wherein the error amplifier is a single-stage operational amplifier.

3. The linear voltage regulator of claim 2, wherein the single-stage operational amplifier comprises a current source configured to establish a bias current, a differential pair configured to amplify a difference between the output voltage and the reference voltage into the first control voltage using the bias current, and an active load for the differential pair to fulfill differential-to-single-ended conversion.

4. The linear voltage regulator of claim 3, wherein the single-stage operational amplifier further comprises a frequency compensation network.

5. The linear voltage regulator of claim 4, wherein the frequency compensation network comprises a serial connection of a resistor and a capacitor that is coupled to the first control voltage.

6. The linear voltage regulator of claim 1, wherein the non-inverting amplifier is a two-stage amplifier comprises an input stage configured to receive the AC coupled voltage and output an amplified voltage and an output stage configured to receive the amplified voltage and output the second control voltage.

7. The linear voltage regulator of claim 6, wherein the input stage has a higher voltage gain than the output stage.

8. The linear voltage regulator of claim 6, wherein the input stage is a self-based inverter.

9. The linear voltage regulator of claim 6, wherein the output stage is a class-AB amplifier.

10. The linear voltage regulator of claim 9, wherein the output stage is an inverter.

11. A method of voltage regulation comprising:
receiving an input voltage and a reference voltage;
incorporating a load configured to draw a load current from an output node;
establishing a first control voltage in accordance with a difference between the reference voltage and an output voltage at the output node using an error amplifier;
converting the input voltage into a first output current supplied to the output node using a first PMOS (p-channel metal oxide semiconductor) transistor in accordance with the first control voltage;
coupling the output voltage to an AC (alternate current) coupled voltage using an AC coupling capacitor;
amplifying the AC coupled voltage into a second control voltage using a non-inverting amplifier; and
converting the input voltage into a second output current supplied to the output node using a second PMOS transistor in accordance with the second control voltage.

12. The method of voltage regulation of claim 11, wherein the error amplifier is a single-stage operational amplifier.

13. The method of voltage regulation of claim 12, wherein the single-stage operational amplifier comprises a current source configured to establish a bias current, a differential pair configured to amplify a difference between the output voltage and the reference voltage into the first control voltage using the bias current, and an active load for the differential pair to fulfill a differential-to-single-ended conversion.

14. The method of voltage regulation of claim 13, wherein the single-stage operational amplifier further comprises a frequency compensation network.

15. The method of voltage regulation of claim 14, wherein the frequency compensation network comprises a serial connection of a resistor and a capacitor that is coupled to the first control voltage.

16. The method of voltage regulation of claim 11, wherein the non-inverting amplifier is a two-stage amplifier comprises an input stage configured to receive the AC coupled voltage and output an amplified voltage and an output stage configured to receive the amplified voltage and output the second control voltage.

17. The method of voltage regulation of claim 16, wherein the input stage has a higher voltage gain than the output stage.

18. The method of voltage regulation of claim 16, wherein the input stage is a self-based inverter.

19. The method of voltage regulation of claim 16, wherein the output stage is a class-AB amplifier.

20. The method of voltage regulation of claim 19, wherein the output stage is an inverter.
